(19) United States
(12) Patent Application Publication
(10) Pub. No.: US 2013/0306132 A1
(43) Pub. Date: Nov. 21, 2013

(54) SOLAR PHOTOELECTRICAL MODULE AND FABRICATION THEREOF

(71) Applicant: INDUSTRIAL TECHNOLOGY RESEARCH INSTITUTE, Hsinchu (TW)

(72) Inventors: Cheng-Yu PENG, Zhongli City (TW); Chung-Teng HUANG, Taichung City (TW); Fu-Ming LIN, Zhudong Township (TW)

(73) Assignee: INDUSTRIAL TECHNOLOGY RESEARCH INSTITUTE, Hsinchu (TW)

(21) Appl. No.: 13/728,791

(22) Filed: Dec. 27, 2012

(30) Foreign Application Priority Data
May 15, 2012 (TW) 101117181

(51) Int. Cl. H01L 31/052; H01L 31/0232

(52) U.S. Cl. CPC H01L 31/0527; H01L 31/02327
USPC 136/246; 438/65

(57) ABSTRACT

A solar photoelectrical module is disclosed, including a back sheet, a plurality of solar cells disposed over the back sheet and adjacent to at least one side of the back sheet, a first package material layer disposed on the back sheet, a second package material layer disposed on the first package material layer, wherein an interface between the first package material layer and the second package material layer comprises a first texture structure.

### CROSS-REFERENCE TO RELATED APPLICATION

This Application claims priority of Taiwan Patent Application No.101117181, filed on May, 15, 2012, the entirety of which is incorporated by reference herein.

### BACKGROUND

1. Technical Field

The technical field relates to a solar photoelectrical module, and more particularly to a solar photoelectrical module with solar cells disposed on periphery areas thereof.

2. Description of the Related Art

Solar cells have become a research focus in the energy field. Solar cells can be arranged on construction sites such as buildings, movable apparatuses such as cars, and portable electronic devices to convert sun ray to electrical energy.

For conventional solar cell technology, solar cells are disposed on a central area of the module. The solar cells block light transmission, such that applications with the solar cells are limited.

### SUMMARY

The disclosure provides a solar photoelectrical module, comprising a back sheet, a plurality of solar cells disposed over the back sheet and adjacent to at least one side of the back sheet, a first package material layer disposed on the back sheet, a second package material layer disposed on the first package material layer, wherein an interface between the first package material layer and the second package material layer comprises a first texture structure.

The disclosure further provides a method for forming a solar photoelectrical module, comprising providing a back sheet, arranging a plurality of solar cells over the back sheet and at least adjacent to one side of the back sheet, forming a first package material layer on the back sheet, laminating the first package material layer with a mold to form a first texture structure in a light guide region, forming a second package material layer on the first package material layer; and attaching an optical plate to the second package material layer.

The disclosure further provides a solar photoelectrical film, comprising a back sheet, a plurality of solar cells disposed over the back sheet and adjacent to at least one side of the back sheet, a first package material layer disposed on the back sheet; and a second package material layer disposed on the first package material layer, wherein an interface between the first package material layer and the second package material layer comprises a first texture structure, and a region among the solar cells is defined as a light guide region, and the light guide region comprises the texture structure.

### BRIEF DESCRIPTION OF DRAWINGS

The disclosure can be more fully understood by reading the subsequent detailed description and examples with references made to the accompanying drawings, wherein,

FIG. 1A shows a plan view of a solar photoelectrical module of an embodiment of the disclosure.

FIG. 1B shows a cross section along line I-I′ of FIG. 1A.

FIG. 1A shows a plan view of a solar photoelectrical module of an embodiment of the disclosure.

FIG. 2 shows a cross section of a solar photoelectrical module of an embodiment of the disclosure.

FIG. 3 shows a cross section of a solar photoelectrical module of an embodiment of the disclosure.

FIG. 4A shows a plan view of a solar photoelectrical module of an embodiment of the disclosure.

FIG. 4B shows a plan view of a solar photoelectrical module of an embodiment of the disclosure.

FIG. 4C shows a plan view of a solar photoelectrical module of an embodiment of the disclosure.

FIG. 5 shows a plan view of a solar photoelectrical module of an embodiment of the disclosure.

FIG. 6 shows a plan view of a solar photoelectrical module of an embodiment of the disclosure.

FIG. 7A shows a plan view of a solar photoelectrical film of an embodiment of the disclosure.

FIG. 7B shows a cross section along line I-I′ of FIG. 7A.

FIG. 8 shows a cross section of a solar photoelectrical film of an embodiment of the disclosure.

### DETAILED DESCRIPTION OF DISCLOSURE

It is understood that specific embodiments are provided as examples to teach the broader inventive concept, and one of ordinary skill in the art can easily apply the teaching of the present disclosure to other methods or apparatus. The following discussion is only used to illustrate the disclosure, not limit the disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

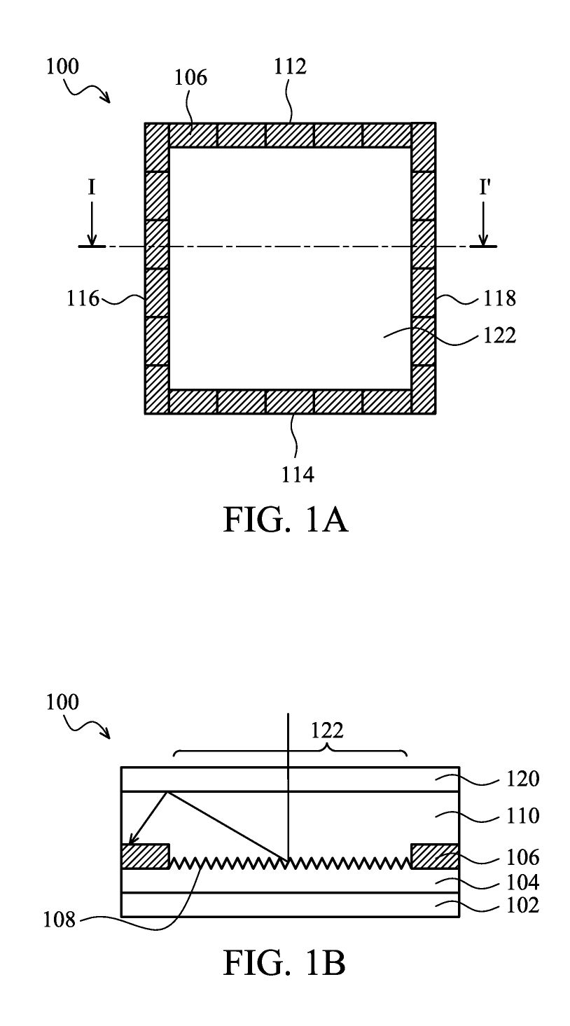

FIG. 1A shows a plan view of a solar photoelectrical module of an embodiment of the disclosure. FIG. 1B shows a cross section along line I-I′ of FIG. 1A. The method for forming a solar photoelectrical module of the embodiment is illustrated in accordance with FIG. 1A and FIG. 1B. Referring to FIG. 1A and FIG. 1B, a back sheet 102 is provided. The back sheet 102 can be glass, metal, semiconductor or plastic substrate, wherein the semiconductor can be silicon, CdTe, CIS-Based semiconductor material, CIGS-Based semiconductor material or GaAs. A first package material layer 104 is formed on the back sheet 102. In an embodiment of the disclosure, the first package material layer 104 can be Ethylene/vinyl acetate (EVA). Next, a mold (not shown) comprising a release film is provided. A lamination process is performed to the first package material layer 104 using the mold, and the first package material layer 104 is further heated by a heating apparatus to form a texture structure 108. A plurality of solar cells 106 are attached on the first packaging material layer 104, wherein the solar cells 106 are respectively adjacent to a first side 112, a second side 114, a third side 116 and a fourth side 118 of the solar photoelectrical module 100, constituting a frame structure. Therefore, as shown in FIG. 1B, the first package material layer 104 is between the solar cells 106 and the back sheet . Thereafter, a second package material layer 110 is formed on the first package material layer 104 and the solar cells 106. In an embodiment of the disclosure, the second package material layer 110 and the first package material layer 104 are formed of the same material. An optical plate 120 such as glass is attached to the second package material layer 110.

The solar photoelectrical module 100 comprises a light guide region 122 surrounded by the solar cells 106. In the embodiment, a texture structure 108 is disposed between the first package material layer 104 and the second package material layer 110 in the light guide region 122. The disclosure can use the texture structure 108 in the light guide region 122 according to zero depth effect to increase a light reflecting angle for light to be horizontally transported to the solar cells 106 disposed at a periphery of the solar photoelectrical module. Thus, light trapping and efficiency of power generation are increased.

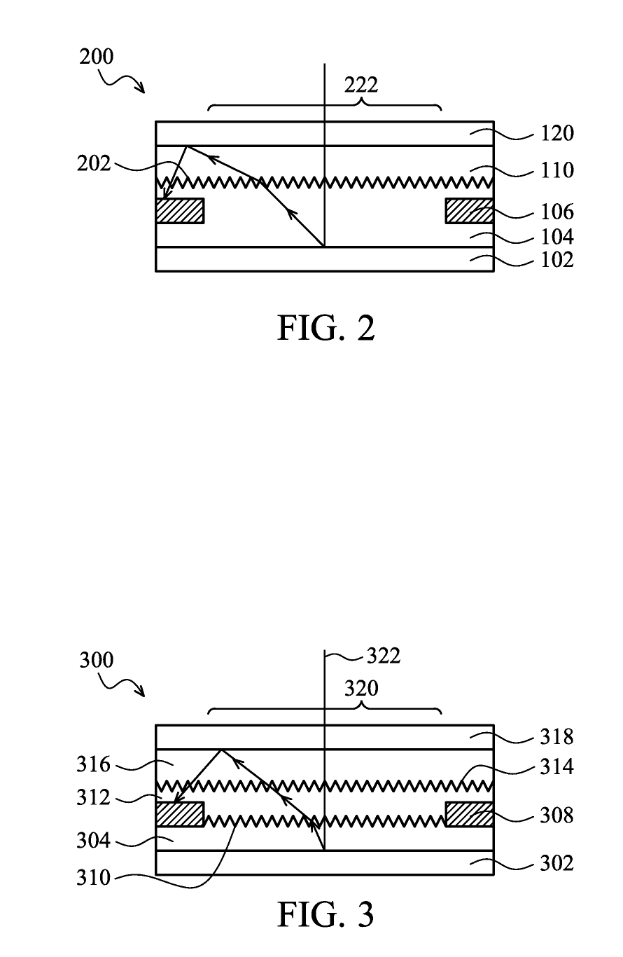

FIG. 2 shows a cross section of a solar photoelectrical module 200 of an embodiment of the disclosure. The solar photoelectrical module 100 of the embodiment shown in FIG. 2 is different from the embodiment of FIG. 1B by the position of the texture structure 202 in the package material layer. Unlike the solar photoelectrical module of FIG. 1B where the texture structure 108 is arranged below the solar cells 106, the embodiment arranges the texture structure 202 above the solar cells 106, and the first package material layer 104 has a portion overlying the solar cells 106. As shown in FIG. 2, the texture structure 202 of the embodiment can increase the light refraction angle for light to be horizontally transported to the solar cells disposed at a periphery of the solar photoelectrical module to increase efficiency of power generation.

FIG. 3 shows a cross section of a solar photoelectrical module 300 of another embodiment of the disclosure. The solar photoelectrical module of the embodiment shown in FIG. 3 is different from the embodiment of FIG. 1B by number and position of the texture structure. A method for forming a solar photoelectrical module of the embodiment is illustrated in accordance with FIG. 3. A back sheet 302 is provided. The back sheet 302 can be glass, metal, semiconductor or plastic, wherein the semiconductor can be silicon, CdTe, CIS-Based semiconductor material, CIGS-Based semiconductor material or GaAs. A first package material layer 304 is formed on the back sheet 302. In an embodiment of the disclosure, the first package material layer 304 can be Ethylene/vinyl acetate (EVA). Next, a mold (not shown) comprising a release film is provided. A lamination process is performed to the first package material layer 304 using the mold, and the first package material layer 304 is further heated by a heating apparatus to form a first texture structure 310 in a light guide region 320. A plurality of solar cells 308 are attached on the first packaging material layer 304, wherein the solar cells 308 are respectively adjacent to a first side, a second side, a third side and a fourth side of the solar photoelectrical module, constituting a frame structure. Thereafter, a second package material layer 312 is formed on the first package material layer 304 and the solar cells 308. In an embodiment of the disclosure, the second package material layer 312 and the first package material layer 304 are formed of the same material. A lamination process is performed to the second package material layer 312 using the mold, and the second package material layer 312 is further heated by a heating apparatus to form a second texture structure 314. A third package material layer 316 is formed on the second package material layer 312. Next, an optical plate 318 such as glass is attached to the third package material layer 316. As shown in FIG. 3, the first texture structure 310 and the second texture structure 314 of the embodiment can increase the light refraction angle for light 322 to be horizontally transported to the solar cells 308 disposed at a periphery of the solar photoelectrical module to increase efficiency of power generation. It is noted that the disclosure does not limit the number and position of the texture structure. The disclosure can comprise more textures in the package material layer, for example the number of the texture structures can be 1 to 99 or more than 99.

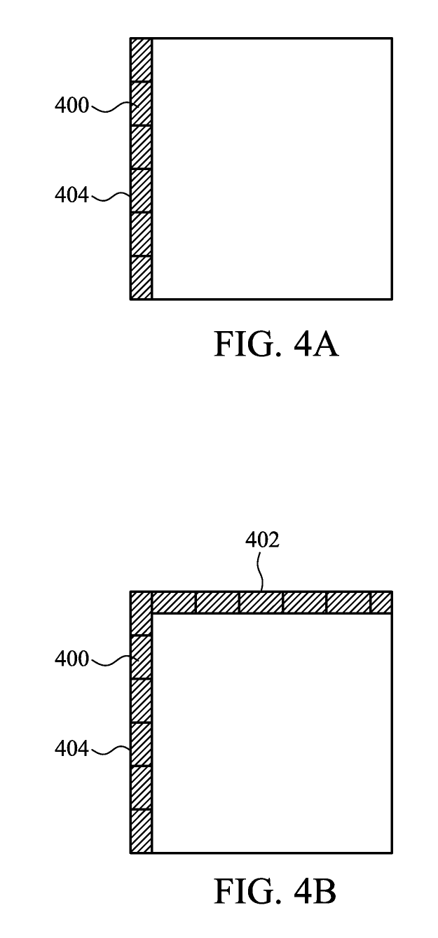

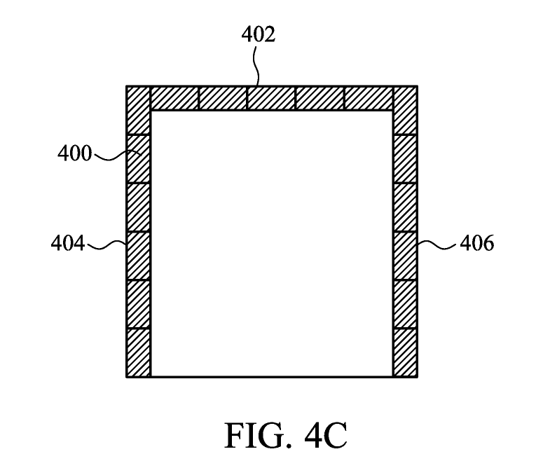

FIG. 4A shows a plan view of a solar photoelectrical module of another embodiment of the disclosure. The solar photoelectrical module of the embodiment is different from the embodiment of FIG. 1A by the position of the solar cells 400. Unlike the solar photoelectrical module of FIG. 1A where the solar cells 106 are arranged neighboring to a first side, a second side, a third side and a fourth side of the solar photoelectrical module, the embodiment arranges the solar cells 400 to neighbor to a third side 404 of the solar photoelectrical module.

FIG. 4B shows a plan view of a solar photoelectrical module of yet another embodiment of the disclosure. The solar photoelectrical module of the embodiment is different from the embodiment of FIG. 1A by the position of the solar cells 400. The embodiment arranges the solar cells 400 to neighbor to a first side 402 and a third side 404 of the solar photoelectrical module. FIG. 4C shows a plan view of a solar photoelectrical module of yet further another embodiment of the disclosure. The embodiment arranges the solar cells 400 to neighbor to a first side 402, a third side 404 and a fourth side 406 of the solar photoelectrical module.

The solar photoelectrical modules described were verified under experimental conditions to get relations between the arrangement of solar cells 400 and light gathering efficiency, which are listed below. Power gain of the solar photoelectrical module shown in FIG. 4A was 22.22%. Power gain of the solar photoelectrical module shown in FIG. 4B was 16.17%. Power gain of the solar photoelectrical module shown in FIG. 4C was 17.36%. Power gain of the solar photoelectrical module shown in FIG. 1A was 16.52%.

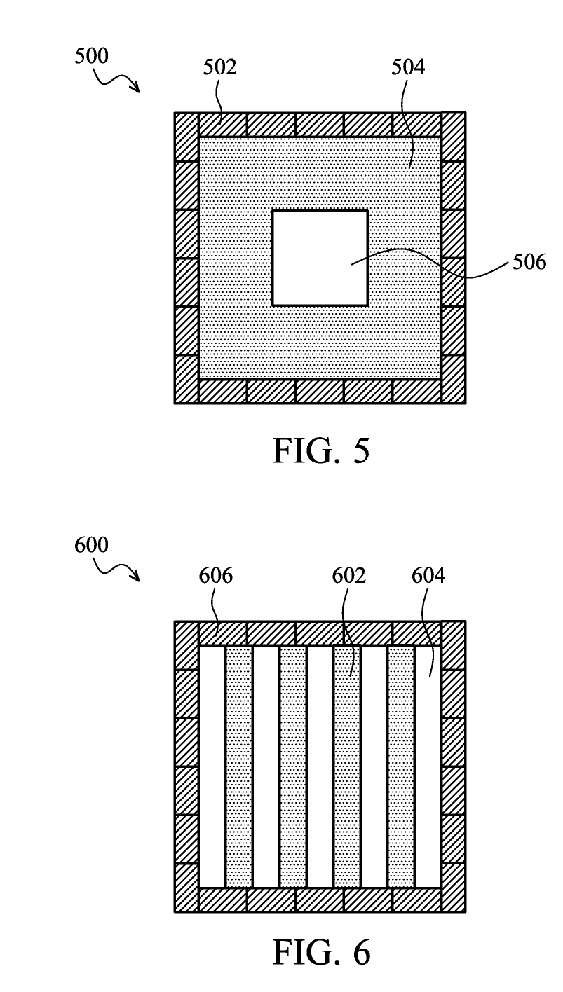

FIG. 5 shows a plan view of a solar photoelectrical module 500 of another embodiment of the disclosure. Referring to FIG. 5, the area surrounded by the solar cells 502 includes not only a light guide region 504 (including texture structures), but also includes a non-light guide region 506 (not including a texture structure) which may be rectangular shaped to increase optical transmission and visible area. The solar cells 502 of the embodiment were verified under experimental conditions to get relations between power gain and a ratio of the light guide region 504 to the entire area of the solar photoelectrical module, which are listed below. Area of the light guide region 504 is defined as B, and the entire area of the light guide region is defined as A. When B/A is equal to zero, power gain is zero. When B/A is equal to 0.02, power gain is 1.38%. When B/A is equal to 0.08, power gain is 2.77%. When B/A is equal to 0.18, power gain is 5.55%. When B/A is equal to 0.32, power gain is 8.33%.

FIG. 6 shows a plan view of a solar photoelectrical module 600 of another embodiment of the disclosure. Referring to FIG. 6, the area surrounded by the solar cells 606 includes alternately arranged light guide regions 602 and non-light guide regions 604, wherein the embodiment can set width of the light guide regions 602 to be 12.5 μm-62.5 μm which is less than the limit visible by a human eye for the region surrounded by solar cells 606 in the solar photoelectrical module 600 to be perspective. The solar photoelectrical modules of the embodiment were verified under experimental conditions to get relations between power gain and a ratio of area of the light guide region 602 to the area of the non-light guide region 604, which are listed below. Area of the light guide region 602 is defined as B, and area of the non-light guide region 604 is defined as C. When C/B is equal to zero, power gain is 16%. When B:C is 1:1, power gain is 8%. When B:C is 2:1, power gain is 5%. When B:C is 2:3, power gain is 7%. When B:C is 3:2, power gain is 7%.

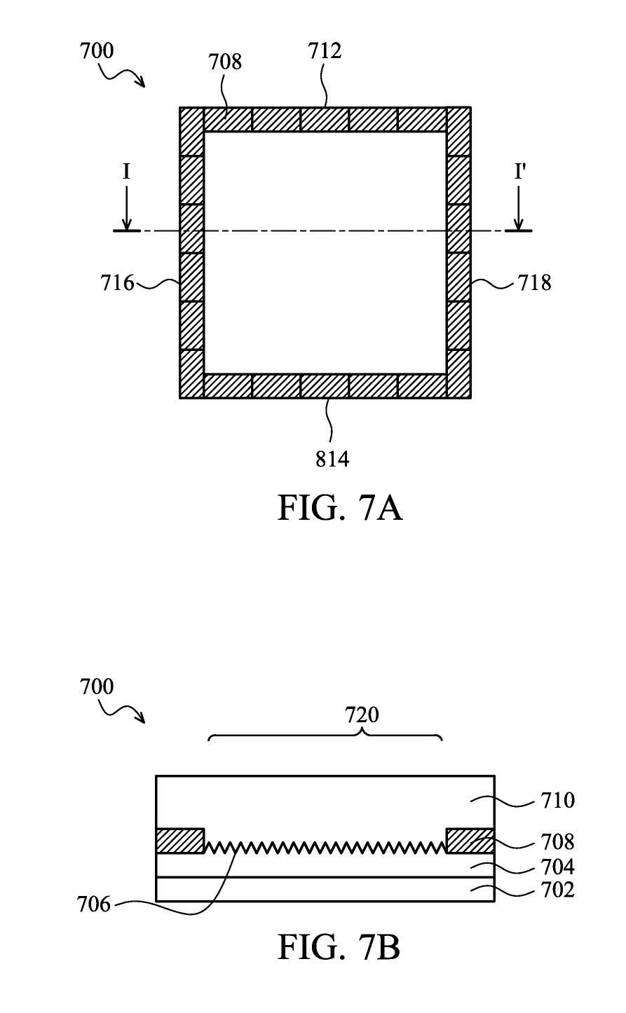

FIG. 7A shows a plan view of a solar photoelectrical film 700 of an embodiment of the disclosure. FIG. 7B shows a cross section along line I-I′ of FIG. 7A. The method for forming a solar photoelectrical film 700 of the embodiment is illustrated in accordance with FIG. 7A and FIG. 7B. Referring to FIG. 7A and FIG. 7B, a back sheet 702 is provided. The back sheet 702 can be glass, metal, semiconductor or plastic substrate, wherein the semiconductor can be silicon, CdTe, CIS-Based semiconductor material, CIGS-Based semiconductor material or GaAs. A first package material layer 704 is formed on the back sheet 702. In an embodiment of the disclosure, the first package material layer 704 can be Ethylene/vinyl acetate (EVA). Next, a mold (not shown) comprising a release film is provided. A lamination process is performed to the first package material layer 704 using the mold, and the first package material layer 704 is further heated by a heating apparatus to form a texture structure 706 in a light guide region 720. A plurality of solar cells 708 are attached on the first packaging material layer 704, wherein the solar cells 708 are respectively adjacent to a first side 712, a second side 714, a third side 716 and a fourth side 718 of the solar photoelectrical film 700, constituting a frame structure. Thereafter, a second package material layer 710 is formed on the first package material layer 704 and the solar cells 708. In an embodiment of the disclosure, the second package material layer 710 and the first package material layer 704 are formed of the same material.

The disclosure can use the texture structure 706 in the light guide region 720 according to zero depth effect to increase a light reflecting angle for the light to be horizontally transported to the solar cells 708 disposed at a periphery of the solar photoelectrical film 700. Thus, light trapping and efficiency of power generation are increased. It is noted that the solar photoelectrical film 700 of the embodiment can be adhered to a glass of a window of a building by a transparent glue for the window to generate electrical power.

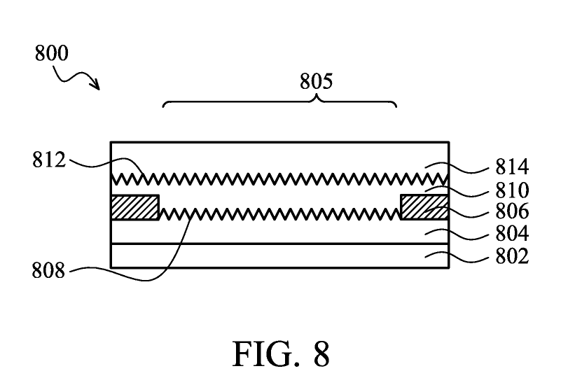

FIG. 8 shows a cross section of a solar photoelectrical film 800 of an embodiment of the disclosure. The solar photoelectrical film 800 of the embodiment shown in FIG. 8 is different from the embodiment of FIG. 7A and FIG. 7B by the number and position of the texture structure. Referring to FIG. 8, the method for forming a solar photoelectrical film 800 of the embodiment comprises providing a back sheet 802, wherein the back sheet 802 can be glass, metal, semiconductor or plastic substrate, and the semiconductor can be silicon, CdTe, CIS-Based semiconductor material, CIGS-Based semiconductor material or GaAs. A first package material layer 804 is formed on the back sheet 802. In an embodiment of the disclosure, the first package material layer 804 can be Ethylene/vinyl acetate (EVA). Next, a mold (not shown) comprising a release film is provided. A lamination process is performed to the first package material layer 804 using the mold, and the first package material layer 804 is further heated by a heating apparatus to form a first texture structure 808 in a light guide region 805. A plurality of solar cells are attached on the first packaging material layer 804, wherein the solar cells 806 are respectively adjacent to a first side, a second side, a third side and a fourth side of the solar photoelectrical film 800, constituting a frame structure. Thereafter, a second package material layer 810 is formed on the first package material layer 804 and the solar cells 806. In an embodiment of the disclosure, the second package material layer 810 and the first package material layer 804 are formed of the same material. A lamination process is performed to the second package material layer 810 using the mold, and the second package material layer 810 is further heated by a heating apparatus to form a second texture structure 812. A third package material layer 814 is formed on the second package material layer 810. As well, f solar photoelectrical film 800 of the embodiment can be adhered to a glass of a window of a building by a transparent glue for the window to generate electrical power.

For simplicity, only a solar photoelectrical module and a solar photoelectrical film comprising one or two texture structures are illustrated. The method for forming a solar photoelectrical module and a solar photoelectrical film can be analogized by the method described. For example, the method for forming a solar photoelectrical film of FIG. 8 can further comprise using the mold to laminate the third package material layer to form a third texture structure, forming a fourth package material layer on the third package material layer, using the mold to laminate the fourth package material layer to form a fourth texture structure, and forming a fifth package material layer on the fourth package material layer. The methods for forming solar photoelectrical module and solar photoelectrical film comprising more texture structures are not described in detail herein.

While the disclosure has been described by way of example and in terms of the preferred embodiments, it is to be understood that the disclosure is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar photoelectrical module, comprising:
a back sheet;
a plurality of solar cells disposed over the back sheet and adjacent to at least one side of the back sheet;
a first package material layer disposed on the back sheet;
a second package material layer disposed on the first package material layer, wherein an interface between the first package material layer and the second package material layer comprises a first texture structure,
wherein the solar photoelectrical module comprises an area neighboring the solar cells or surrounded by the solar cells, and a light guide region in the area comprises the first texture structure.

2. The solar photoelectrical module as claimed in claim 1, further comprising an optical plate disposed on the second package material layer.

3. The solar photoelectrical module as claimed in claim 1, wherein the solar cells are disposed over the back sheet and are adjacent to a first side and a second side of the back sheet.

4. The solar photoelectrical module as claimed in claim 3, further comprising a plurality of solar cells disposed over the back sheet and adjacent to a third side of the back sheet.

5. The solar photoelectrical module as claimed in claim 4, further comprising a plurality of solar cells disposed over the back sheet and adjacent to a fourth side of the back sheet, wherein the solar cells constitute a frame structure.

6. The solar photoelectrical module as claimed in claim 1, wherein the first package material layer and the second package material layer comprise the same material.

7. The solar photoelectrical module as claimed in claim 6, wherein the first package material layer and the second package material layer comprise Ethylene/vinyl acetate (EVA).

8. The solar photoelectrical module as claimed in claim 1, wherein the first package material layer is between the solar cells and the back sheet.

9. The solar photoelectrical module as claimed in claim 1, wherein the first package material layer has a portion overlying the solar cells.

10. The solar photoelectrical module as claimed in claim 1, further comprising a plurality of package material layers disposed between the second package material layer and the optical plate, wherein an interface between the package material layers comprises a second texture structure.

11. The solar photoelectrical module as claimed in claim 1, wherein the light guide region surrounds a non-light guide region, and the non-light guide region does not comprise the texture structure.

12. The solar photoelectrical module as claimed in claim 1, wherein the light guide region further comprises a non-light guide region not comprising the first texture structure.

13. The solar photoelectrical module as claimed in claim 12, wherein light guide region and the non-light guide region are strip shaped, and light guide region and the non-light guide region are alternately arranged.

14. The solar photoelectrical module as claimed in claim 13, wherein width of the light guide region is 12.5 μm-62.5 μm.

15. A method for forming a solar photoelectrical module, comprising:
providing a back sheet;
forming a first package material layer on the back sheet;
arranging a plurality of solar cells over the back sheet and at least adjacent to one side of the back sheet;
laminating the first package material layer with a mold to form a first texture structure;
forming a second package material layer on the first package material layer; and
attaching an optical plate to the second package material layer.

16. The method for forming a solar photoelectrical module as claimed in claim 15, further comprising:
laminating the second package material layer with the mold to form a second texture structure; and
forming a third package material layer on the second package material layer.

17. The method for forming a solar photoelectrical module as claimed in claim 15, wherein first package material layer and the second package material layer comprise the same material.

18. The method for forming a solar photoelectrical module as claimed in claim 17, wherein the first package material layer and the second package material layer comprise Ethylene/vinyl acetate (EVA).

19. The method for forming a solar photoelectrical module as claimed in claim 15, wherein the mold comprises a release film thereon.

20. The method for forming a solar photoelectrical module as claimed in claim 15, further comprising disposing a plurality of solar cells to be adjacent to a second side, a third side and a fourth side of the back sheet, wherein the solar cells constitute a frame structure.
